(19) United States
(12) Patent Application Publication
(10) Pub. No.: US 2024/0047267 A1
(43) Pub. Date: Feb. 8, 2024

(54) TUNGSTEN GAP FILL WITH HYDROGEN PLASMA TREATMENT

(71) Applicant: Applied Materials, Inc., Santa Clara, CA (US)

(72) Inventors: Tsung-Han YANG, Sunnyvale, CA (US); Shiyu YUE, San Jose, CA (US); Rongjun WANG, Dublin, CA (US)

(21) Appl. No.: 18/228,300

(22) Filed: Jul. 31, 2023

Related U.S. Application Data
(60) Provisional application No. 63/395,762, filed on Aug. 5, 2022.

(51) Int. Cl. H01L 21/768; H01J 37/32; C23C 14/56; C23C 14/58; C23C 16/06; C23C 14/06; C23C 16/455; C23C 14/18

(52) U.S. Cl. CPC H01L 21/76826; H01L 21/76843; H01L 21/76877; H01J 37/32091; H01J 37/32899; C23C 14/568; C23C 14/5846; C23C 16/06; C23C 14/0641; C23C 16/45525; C23C 14/18; H01J 2237/332

(57) ABSTRACT

Embodiments of methods and associated apparatus for filling features in a silicon-containing dielectric layer of a substrate are provided herein. In some embodiments, a method of filling features in a silicon-containing dielectric layer of a substrate includes: depositing a discontinuous liner layer in the feature via a physical vapor deposition (PVD) process in a first process chamber; performing a hydrogen plasma process in a second process chamber to form silicon-hydrogen bonds on surfaces of the feature not covered by the discontinuous liner layer; and depositing a bulk tungsten layer on the discontinuous liner layer and over the silicon-hydrogen bonds to fill the feature with tungsten in a third process chamber.

### CROSS-REFERENCE TO RELATED APPLICATIONS

This application claims benefit of U.S. provisional patent application Ser. No. 63/395,762, filed Aug. 5, 2022, which is herein incorporated by reference in its entirety.

### FIELD

Embodiments of the present disclosure generally relate to processing of substrates.

### BACKGROUND

Integrated circuits are formed by processes that produce intricately patterned material layers on substrate surfaces. Tungsten is used in the semiconductor industry as a lower resistivity conductor with minimal electro-migration. Tungsten may be used to fill features as contacts for transistors and in the formation of vias between layers of integrated devices. Tungsten may also be used for interconnects in logic and memory devices due to tungsten's stability and low resistivity. However, conventional tungsten metal gap fill processes may be prone to voids during gap fill due to early pinch-off at overhangs.

Accordingly, the inventors have provided embodiments of improved processes to facilitate void-free tungsten gap fill.

### SUMMARY

Embodiments of methods and associated apparatus for filling features in a silicon-containing dielectric layer of a substrate are provided herein. In some embodiments, a method of filling features in a silicon-containing dielectric layer of a substrate includes: depositing a discontinuous liner layer in the feature via a physical vapor deposition (PVD) process in a first process chamber; performing a hydrogen plasma process in a second process chamber to form silicon-hydrogen bonds on surfaces of the feature not covered by the discontinuous liner layer; and depositing a bulk tungsten layer on the discontinuous liner layer and over the silicon-hydrogen bonds to fill the feature with tungsten in a third process chamber.

In some embodiments, a method of filling a feature in a silicon-containing dielectric layer of a substrate includes: depositing a discontinuous liner layer in the feature via a physical vapor deposition (PVD) process in a first process chamber; performing a hydrogen plasma process in a second process chamber to form silicon-hydrogen bonds on surfaces of the feature not covered by the discontinuous liner layer; and depositing a bulk tungsten layer on the discontinuous liner layer and over the silicon-hydrogen bonds without a nucleation layer to fill the feature with tungsten via an atomic layer deposition (ALD) process in a third process chamber.

In some embodiments, a non-transitory computer readable medium comprising one or more processors, that when executed, perform a method of filling a feature in a silicon-containing dielectric layer of a substrate that includes: depositing a discontinuous liner layer in the feature via a physical vapor deposition (PVD) process in a first process chamber; performing a hydrogen plasma process in a second process chamber to form silicon-hydrogen bonds on surfaces of the feature not covered by the discontinuous liner layer; and depositing a bulk tungsten layer on the discontinuous liner layer and over the silicon-hydrogen bonds to fill the feature with tungsten in a third process chamber.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 depicts a flow chart of a method of filling a feature in a silicon-containing dielectric layer of a substrate in accordance with at least some embodiments of the present disclosure.

FIG. 2 depicts a cross-sectional side view of a portion of a substrate having a discontinuous liner layer deposited in the feature in accordance with at least some embodiments of the present disclosure.

FIG. 3 depicts a cross-sectional side view of a portion of a substrate after performing a hydrogen plasma process in accordance with at least some embodiments of the present disclosure.

FIG. 4 depicts a cross-sectional side view of a portion of a substrate after depositing a bulk tungsten layer in accordance with at least some embodiments of the present disclosure.

FIG. 5 depicts a multi-chamber processing tool in accordance with at least some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

The methods and apparatus described herein provide void-free or substantially void-free tungsten gap fill in substrates. The embodiments provided herein may be used to fill features formed in substrates such as vias, trenches, or the like. Tungsten is widely used as metallic interconnect in logic and memory devices, because of tungsten's unique stability and low resistivity. However, along with technological advances and smaller feature sizes comes an increasing need for a metal fill solution with void-free or substantially void-free gap fill. Conventionally, a nucleation layer is deposited in the feature before a bulk tungsten fill process for efficient tungsten bulk fill process with reduced or no voids. However, the nucleation layer is a high resistance film, which leads to significantly higher levels of stack resistivity. Higher stack resistivity leads to increased power consumption and reduced performance of devices. Thus, the methods provided herein are directed at performing a hydrogen plasma process before a bulk tungsten fill process to advantageously provide a good gap fill in the feature without having a nucleation layer in the feature.

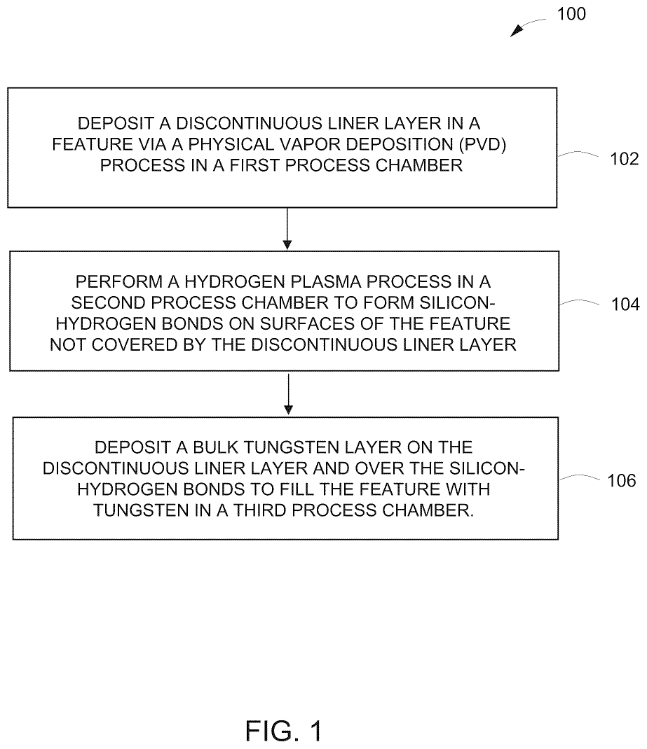

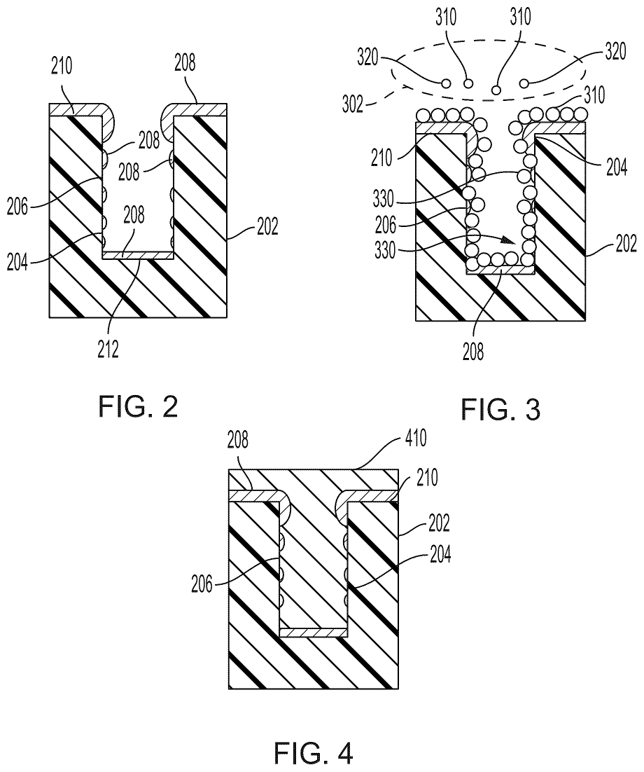

FIG. 1 depicts a flow chart of a method 100 of filling a feature (e.g., feature 204) in a substrate (e.g., substrate 202) in accordance with at least some embodiments of the present disclosure. At 102, the method 100 includes depositing a discontinuous liner layer (e.g., discontinuous liner layer 208) in the feature via a physical vapor deposition (PVD) process in a first process chamber (e.g., one of process chambers 514A through 514D). The feature in generally formed in a silicon-containing dielectric layer of the substrate. FIG. 2 depicts a cross-sectional side view of a portion of a substrate 202 having a discontinuous liner layer 208 deposited in the feature 204 in accordance with at least some embodiments of the present disclosure. In some embodiments, the feature has a critical dimension of about 20 nanometers or less.

The feature 204 may be a via, a trench, or the like, formed in the substrate 202. The feature 204 may extend into the substrate 202 from a field region 210 or upper surface of the substrate 202. The feature 204 may include a bottom surface 212 and sidewalls 206 that extend from the bottom surface 212 to the field region 210. In some embodiments, the discontinuous liner layer 208 comprises or consists essentially of titanium nitride (TiN) or tungsten (e.g., greater than or equal to 95 percent).

In some embodiments, the PVD process is performed at a temperature of about 200 to about 500 degrees Celsius. In some embodiments, the PVD process is performed at a chamber pressure of about 0.1 to about 10 mTorr. The discontinuous liner layer 208 generally covers at least portions of the bottom surface 212 of the feature 204 as well as portions of sidewalls 206 of the feature 204. The discontinuous liner layer 208 may also be deposited on the field region (e.g., field region 210) of the substrate 202 and form overhang regions 312 proximate a front opening 316 of the features 204. The discontinuous nature of the discontinuous liner layer 208 provides a poor underlayer for subsequent bulk fill of the feature 204.

At 104, the method 100 includes performing a hydrogen plasma process in a second process chamber (e.g., one of process chambers 514A through 514D) to form silicon-hydrogen bonds (e.g., silicon-hydrogen bonds 330) on surfaces of the feature not covered by the discontinuous liner layer. The hydrogen plasma process advantageously overcomes the issue of the discontinuous liner layer 208 by providing a substantially continuous underlayer along surfaces of the feature comprising silicon-hydrogen bonds and the discontinuous liner layer 208 for a bulk fill process. In some embodiments, the hydrogen plasma process is performed in a capacitively coupled plasma (CCP) chamber. In some embodiments, the hydrogen plasma process is performed at a temperature of about 200 to about 500 degrees Celsius.

The hydrogen plasma process is performed using a plasma comprising hydrogen ions (e.g., hydrogen ions 310). In some embodiments, the plasma comprises hydrogen ions and argon ions (e.g., argon ions 320). In some embodiments, an amount of hydrogen plasma in the plasma is greater than an amount of argon ions in the plasma. In some embodiments, a ratio between the hydrogen ions and the argon ions is about 4:1 to about 50:1. For example, in some embodiments, the ratio between the hydrogen ions and the argon ions is about 35:1 to about 50:1. In some embodiments, the ratio between the hydrogen ions and the argon ions is about 8:1 to about 12:1. In some embodiments, a chamber pressure during the hydrogen plasma process is greater than about 100 mTorr. For example, in some embodiments, a chamber pressure during the hydrogen plasma process is about 0.3 to about 11 Torr. In some embodiments, the chamber pressure during the hydrogen plasma process is about 0.3 to about 1.8 Torr. In some embodiments, the chamber pressure during the hydrogen plasma process is about 9 to about 11 Torr. In some embodiments, the hydrogen plasma process is performed for about 90 to about 250 seconds.

FIG. 3 depicts a cross-sectional side view of a portion of a substrate 202 after performing a hydrogen plasma process in accordance with at least some embodiments of the present disclosure. The hydrogen plasma process comprises exposing the substrate 202 and the discontinuous liner layer 208 to a plasma 302. In some embodiments, the plasma 302 includes hydrogen ions 310 for bonding with exposed silicon on surfaces of the feature 204 not covered by the discontinuous liner layer 208. Hydrogen ions 310 bond with silicon in the substrate 202 to form silicon-hydrogen bonds 330. In some embodiments, the plasma 302 includes argon ions 320 in combination with the hydrogen ions 310 to aid in stabilizing the plasma 302.

At 106, the method 100 includes depositing a bulk tungsten layer (e.g., bulk tungsten layer 410) consisting essentially of tungsten on the discontinuous liner layer and over the silicon-hydrogen bonds to fill the feature with tungsten in a third process chamber (e.g., one of process chambers 514A through 514D). In some embodiments, consisting essentially of tungsten is greater than or equal to 95 percent tungsten. Depositing the bulk tungsten is generally performed via a suitable deposition process in an atomic layer deposition (ALD) chamber or chemical vapor deposition (CVD) chamber. In some embodiments, the CVD process or the ALD process is performed at a temperature of about 200 to about 500 degrees Celsius. In some embodiments, there are no etch processes performed between the PVD deposition process of 102 and the bulk tungsten deposition process of 106. The hydrogen plasma treatment is generally performed at a chamber pressure that is greater than a chamber pressure during each of the PVD deposition of 102 or ALD/CVD deposition of 106.

FIG. 4 depicts a cross-sectional side view of a portion of a substrate 202 after depositing a bulk tungsten layer 410 in accordance with at least some embodiments of the present disclosure. The silicon-hydrogen bonds 330 formed at 104 act as a soak at the bottom surface 212 and sidewalls 206 of the feature 204 for ALD/CVD growth of the bulk tungsten layer 410 without any nucleation layer. The bulk tungsten layer 410 fills the feature 204 void-free or with substantially no voids. In some embodiments, the method 100 includes performing a planarization process, such as chemical-mechanical planarization, of the bulk tungsten layer 410 after depositing the bulk tungsten layer to planarize the bulk tungsten layer 410.

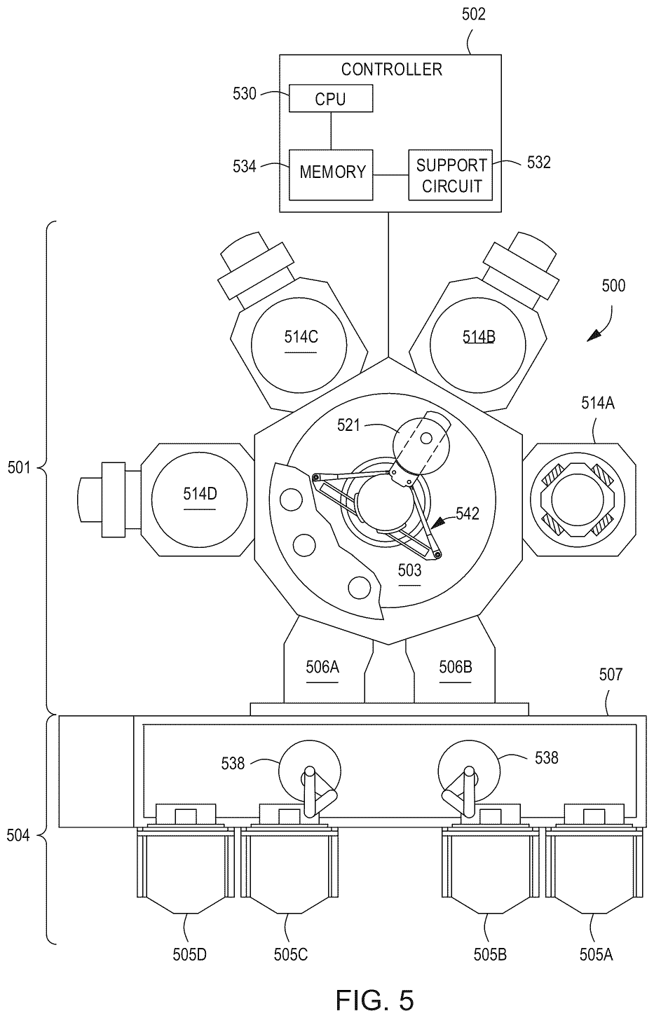

In some embodiments, the method 100 is performed in a multi-chamber processing tool (e.g., multi-chamber processing tool 500) with no vacuum break between the first process chamber, the second process chamber, and the third process chamber. For example, FIG. 5 depicts a multi-chamber processing tool 500 in accordance with at least some embodiments of the present disclosure. The multi-chamber processing tool 500 may be suitable to perform the methods of the present disclosure. The methods described herein may be practiced using other multi-chamber processing tools having suitable process chambers coupled thereto, or in other suitable process chambers. For example, in some embodiments, the inventive methods discussed above may be advantageously performed in a multi-chamber processing tool such that there are very limited or no vacuum breaks between processing steps. For example, no vacuum breaks may limit or prevent contamination of any substrates being processed in the multi-chamber processing tool.

The multi-chamber processing tool 500 generally includes a processing platform 501 that is vacuum-tight, a factory interface 504, and a system controller 502. The processing platform 501 includes a plurality of process chambers, such as 514A, 514B, 514C, and 514D, operatively coupled to a transfer chamber 503 that is under vacuum. In some embodiments, the first process chamber may be process chamber 514A, the second process chamber may be 514B, and the third process chamber may be process chamber 514C. In some embodiments, the multi-chamber processing tool 500 may include a plurality of transfer chambers 503 in fluid communication with each other to accommodate a greater number of process chambers in a vacuum-tight environment. The factory interface 504 is selectively operatively coupled to the transfer chamber 503 by one or more load lock chambers, such as 506A and 506B shown in FIG. 5.

In some embodiments, the factory interface 504 comprises at least one docking station 507 and at least one factory interface robot 538 to facilitate the transfer of substrates 521, such as the substrate 202. The at least one docking station 507 is configured to accept one or more front opening unified pods (FOUP). Four FOUPS, identified as 505A, 505B, 505C, and 505D, are shown in FIG. 5. The at least one factory interface robot 538 is configured to transfer the substrates 521 from the factory interface 504 to the processing platform 501 through the load lock chambers 506A, 506B. Each of the load lock chambers 506A and 506B have a first port coupled to the factory interface 504 and a second port coupled to the transfer chamber 503. The load lock chambers 506A and 506B are coupled to a pressure control system (not shown) which pumps down and vents the load lock chambers 506A and 506B to facilitate passing the substrates between the vacuum environment of the transfer chamber 503 and the substantially ambient (e.g., atmospheric) environment of the factory interface 504.

The transfer chamber 503 has a vacuum robot 542 disposed therein. The vacuum robot 542 is capable of transferring the substrates 521 between the load lock chamber 506A and 506B and the plurality of process chambers 514A, 514B, 514C, and 514D. In some embodiments, the vacuum robot 542 includes one or more upper arms that are rotatable about a respective shoulder axis. In some embodiments, the one or more upper arms are coupled to respective forearm and wrist members such that the vacuum robot 542 can extend into and retract from any processing chambers coupled to the transfer chamber 503.

The plurality of process chambers 514A, 514B, 514C, and 514D, are coupled to the transfer chamber 503. Each of the plurality of process chambers 514A, 514B, 514C, and 514D may comprise a suitable process chamber for substrate processing, such as a chemical vapor deposition (CVD) chamber, an atomic layer deposition (ALD) chamber, a physical vapor deposition (PVD) chamber, a plasma enhanced atomic layer deposition (PEALD) chamber, an etch chamber (i.e., dry etch chamber), a preclean/annealing chamber, or the like. In some embodiments, the plurality of process chambers 514A, 514B, 514C, and 514D comprise at least one PVD chamber configured to deposit the discontinuous liner layer 208 and at least one ALD or CVD chamber configured to deposit the bulk tungsten layer 410.

A system controller 502 controls the operation of the multi-chamber processing tool 500 using a direct control of the process chambers 514A, 514B, 514C, and 514D or alternatively, by controlling the computers (or controllers) associated with the process chambers 514A, 514B, 514C, and 514D. The system controller 502 generally includes a central processing unit (CPU) 530, a memory 534, and a support circuit 532. The CPU 530 may be one of any form of a general-purpose computer processor that can be used in an industrial setting. The support circuit 532 is conventionally coupled to the CPU 530 and may comprise a cache, clock circuits, input/output subsystems, power supplies, and the like. Software routines, such as processing methods as described above may be stored in the memory 534 and, when executed by the CPU 530, transform the CPU 530 into a system controller 502. The software routines may also be stored and/or executed by a second controller (not shown) that is located remotely from the multi-chamber processing tool 500.

In operation, the system controller 502 enables data collection and feedback from the respective chambers and systems to optimize performance of the multi-chamber processing tool 500 and provides instructions to system components for performing the methods described herein. For example, the memory 534 can be a non-transitory computer readable storage medium having instructions that when executed by the CPU 530 (or system controller 502) perform the methods described herein.

While the foregoing is directed to embodiments of the present disclosure, other and further embodiments of the disclosure may be devised without departing from the basic scope thereof.

1. A method of filling a feature in a silicon-containing dielectric layer of a substrate, comprising:
depositing a discontinuous liner layer in the feature via a physical vapor deposition (PVD) process in a first process chamber;
performing a hydrogen plasma process in a second process chamber to form silicon-hydrogen bonds on surfaces of the feature not covered by the discontinuous liner layer; and
depositing a bulk tungsten layer consisting essentially of tungsten on the discontinuous liner layer and over the silicon-hydrogen bonds to fill the feature with tungsten in a third process chamber.

2. The method of claim 1, wherein the method is performed in a multi-chamber processing tool with no vacuum break between the first process chamber, the second process chamber, and the third process chamber.

3. The method of claim 1, wherein the hydrogen plasma process is performed using a plasma comprising hydrogen ions and argon ions.

4. The method of claim 3, wherein a ratio between the hydrogen ions and the argon ions is about 4:1 to about 45:1.

5. The method of claim 1, wherein the discontinuous liner layer comprises titanium nitride (TiN) or tungsten.

6. The method of claim 1, wherein a chamber pressure during the hydrogen plasma process is greater than about 100 mTorr.

7. The method of claim 1, wherein depositing the bulk tungsten layer is performed in an atomic layer deposition (ALD) chamber or chemical vapor deposition (CVD) chamber.

8. The method of claim 1, wherein the hydrogen plasma process is performed for about 90 to about 250 seconds.

9. The method of claim 1, wherein a chamber pressure during the hydrogen plasma process is about 0.3 to about 1.8 Torr.

10. The method of claim 1, wherein the hydrogen plasma process is performed in a capacitively coupled plasma (CCP) chamber.

11. The method of claim 1, wherein the feature has a critical dimension of about 20 nanometers or less.

12. A method of filling a feature in a silicon-containing dielectric layer of a substrate, comprising:
depositing a discontinuous liner layer in the feature via a physical vapor deposition (PVD) process in a first process chamber;
performing a hydrogen plasma process in a second process chamber to form silicon-hydrogen bonds on surfaces of the feature not covered by the discontinuous liner layer; and
depositing a bulk tungsten layer consisting essentially of tungsten on the discontinuous liner layer and over the silicon-hydrogen bonds without a nucleation layer to fill the feature with tungsten via an atomic layer deposition (ALD) process in a third process chamber.

13. The method of claim 12, wherein the discontinuous liner layer comprises titanium nitride (TiN) or tungsten.

14. The method of claim 12, wherein the hydrogen plasma process is performed using a plasma comprising hydrogen ions and argon ions, wherein an amount of hydrogen plasma in the plasma is greater than an amount of argon ions in the plasma.

15. A non-transitory computer readable medium comprising one or more processors, that when executed, perform a method of filling a feature in a silicon-containing dielectric layer of a substrate, comprising:
depositing a discontinuous liner layer in the feature via a physical vapor deposition (PVD) process in a first process chamber;
performing a hydrogen plasma process in a second process chamber to form silicon-hydrogen bonds on surfaces of the feature not covered by the discontinuous liner layer; and
depositing a bulk tungsten layer consisting essentially of tungsten on the discontinuous liner layer and over the silicon-hydrogen bonds to fill the feature with tungsten in a third process chamber.

16. The non-transitory computer readable medium of claim 15, wherein the method is performed in a multi-chamber processing tool with no vacuum break between the first process chamber, the second process chamber, and the third process chamber.

17. The non-transitory computer readable medium of claim 15, wherein the hydrogen plasma process is performed using a plasma comprising hydrogen ions for bonding with silicon in the substrate and argon ions to stabilize the plasma.

18. The non-transitory computer readable medium of claim 15, wherein at least one of:
a chamber pressure during the hydrogen plasma process is greater than about 100 mTorr, or
wherein the hydrogen plasma process is performed for about 90 to about 250 seconds.

19. The non-transitory computer readable medium of claim 15, wherein depositing the bulk tungsten layer is performed in an atomic layer deposition (ALD) chamber or chemical vapor deposition (CVD) chamber.

20. The non-transitory computer readable medium of claim 15, wherein the discontinuous liner layer comprises titanium nitride (TiN) or tungsten.
